(19) United States
(12) Patent Application Publication
(10) Pub. No.: US 2006/0023275 A1
(43) Pub. Date: Feb. 2, 2006

(54) Method for conversion and reproduction of film images through a digital process

(75) Inventors: Phillip J. Feiner, Studio City, CA (US); Christopher B. Bushman, North Hollywood, CA (US); James D. Houston, Altadena, CA (US); Denis Pierre Leconte, Canoga Park, CA (US)

Correspondence Address: Ross E. Davidson;Quinn Emanuel Urquhart Oliver & Hedges LLP, 865 South Figueroa Street, Los Angeles, CA, 90017, US

(73) Assignee: Pacific Title & Arts Studio, Inc.

(21) Appl. No.: 11/192,201

(22) Filed: Jul. 28, 2005

Related U.S. Application Data
(60) Provisional application No. 60/592,979, filed on Jul. 30, 2004.

(51) Int. Cl. H04N 1/23; G03F 3/08

(52) U.S. Cl. 358/527; 358/518; 358/515; 358/302

(57) ABSTRACT

The present invention relates to a method for directly converting visual images, such as motion picture film, to a digital format and recording stable archival film elements so that a digitally-recorded film master or other visual image can be accurately reproduced without the necessity of creating a digital intermediate.

### CROSS-REFERENCE TO RELATED APPLICATIONS

This application claims priority and makes reference to U.S. Provisional Application 60/592,979 filed on Jul. 30, 2004, the entire contents of which application is incorporated herein by reference.

### STATEMENT REGARDING FEDERALLY SPONSORED RESEARCH OR DEVELOPMENT

Not applicable.

### INCORPORATION-BY-REFERENCE OF MATERIAL SUBMITTED ON A COMPACT DISC

Not applicable.

### BACKGROUND OF THE INVENTION

1. Field of the Invention

The present invention relates to a method for the direct conversion of visual images, such as those captured on motion picture film, and other sources, to a digital format without the generation of a Digital Intermediate.

2. Description of Related Art

The use of YCM visual masters, as a means to create color images, was among the earliest technologies for creating color film images, introduced even prior to the introduction of color negative film types. The prior methods started with the development of three-strip black and white cameras in the 1930's. This later led to the use of three-strip positive separations for duplication of original camera color negatives. The use of black and white separation elements allows long-term archiving of film elements as black and white film is not susceptible to fading of color dyes.

In practice, positive separations are produced by contact between the exposed original negative and an unexposed black and white positive type film emulsion. The color negative and unexposed black and white positive film are exposed to a broad light source which is filtered by a red, green, or blue separation filter. This produces a black and white film element containing the separate luminance of each color channel. Each of the black and white film elements are developed at different gamma settings which are the inverse of the gamma of the target reproduction color negative. Gamma, in the photographic industries, refers to the standard method of evaluating contrast by plotting exposure versus developed density to determine the control settings for chemical developing of photographic film. Developing of black and white film at different gammas introduces the possibility of chemical processing errors in the reproduction of the master element.

This YCM process can be reversed by placing an unexposed color negative next to the exposed black and white positive film element and using the appropriate color filter on the light source for each of the color records. This process as it has developed is known as a photographic film color separation process. Details on the traditional YCM process can be found in the Kodak Publication “Kodak Panchromatic Separation Film 2238” Kodak Publication No. H-1-328×, CAT 145 0200, 1999.

A variant of this original optical process was developed where all of the images are placed on one strip of black and white film. This prior method was known as S.E. or successive exposure. This method has an advantage in that a single gamma setting is used for developing, and that each color record is next to each other minimizing errors due to film shrinkage over time. A digital version of this process was developed in the early 1990's in which digital black and white S.E. original negatives were recorded. These elements were intended as the original color source (i.e. the negative) for the film and were thus not intended as duplication elements.

Thus, prior methods of archiving and reproducing motion picture and other visual images required that YCM masters be created in a multi-step process involving the creation of an original camera negative or a Digital Intermediate (“DI”) negative, followed by conversion of one of those negatives on a continuous contact printer to a YCM master positive. The disadvantage of this prior method is that it incorporates an additional conversion step which increases the risk that the visual image will be artistically altered from its author's original work and vision.

It is desirable to create new master copies of film and other visual works in order to preserve them because the color dyes used in color film and other materials used in the visual images have a limited life span. For example, in the case of motion picture film, once the non-linear fading in the most vulnerable layer of the film exceeds 20-30% fading, heroic measures will be required to correct the then visibly reduced contrast and color saturation. The need for correction of this problem is determined by comparing color timing values when the film element was new, against the current corrections required to re-establish the prior values. If the difference of any one color is in the 20-30% range, the film element must be re-timed, answer printed, and approved. This requires that a new intermediate positive be made (depending on the need for more internegatives) and if the condition of the faded film element still permits it, a set of panchromatic separations. This task is not complete without making a new intermediate negative from these three pan separation elements, and from this intermediate negative a check print is made to make sure that the job was done right.

One example of the prior art method to restore faded elements is described in the SMPTE Journal of July 1981, pp. 591-596 by C. Bradley Hunt of the Eastman Kodak Company. The Hunt reference describes the methods that include making a color contrast correcting color mask on panchromatic separation film that is printed with the faded element Using this prior art method is costly as it requires a pin-registered optical step printing, along with a wetgate procedure to reduce scratches, and then processing those positive separations specially to achieve the correct contrast. After they are proven to improve the image, each is printed back onto a color intermediate film (with a negative image) from which a print is made in the usual way.

Another prior method involves making three black-and-white color separation masks that are printed in separate optical bipack printing steps, along with the faded color film element. Such restoration methods are not often used as they are costly and very time-consuming in the optical facility and in the laboratory. Considering the effort required to correct dye fading of an old film element, it is hard to justify the decision not to have done so when the original film element was still new. The use of black and white separation masters found use in prior methods of archiving and reproducing motion picture and other visual images. Positive separation masters are typically made from the original camera negative with a fine grain positive film stock, such as Kodak Panchromatic Separation Film 2238.

This prior process is also used when the original camera negative is instead a digitally-recorded, digital intermediate negative (DI negative). The DI negative may not contain all of the information from the original camera negative because of scanning losses, and because current practice in DI recording is to create recorded images with a resolution of 2048 horizontal pixels. A further reduction in quality then occurs when the DI negative is contact printed onto the duplicating positive film stocks, which increases the risk that the visual image will be artistically altered from its author's original work and vision. FIG. 1 shows an example of the prior method.

### BRIEF SUMMARY OF THE INVENTION

The present invention relates to a method for the direct conversion of visual images, such as those captured on motion picture film, and other sources, to a digital format without the generation of a Digital Intermediate. The produced film elements are recombined on a contact printer to create a duplicate color negative, or scanned back into a digital format so that a color negative can be digitally re-recorded. When the produced film elements are recombined on a contact printer, or scanned back into a digital format, the accuracy and artistic integrity of the reproduction of the visual images is enhanced because the final, fully reproduced digital version is not the product of a duplication step upon a contact printer from a recorded digital intermediate color negative. The digital process of this invention allows control of the quality of the reproduction in a manner which is not possible with prior art methods. The instant invention describes a process that allows digital reproduction of a visual image where the quality of the reproduction can be controlled and enhanced in its digital form. In addition, the final, fully reproduced visual image has one less step in the reproduction process since a contact printer is not used to make the YCM positives, thus retaining more of the original image quality.

### BRIEF DESCRIPTION OF THE DRAWINGS

FIG. 1 illustrates the general flow of the process of the prior art method in which a Digital Intermediate negative is created with duplication via a continuous contact printer.

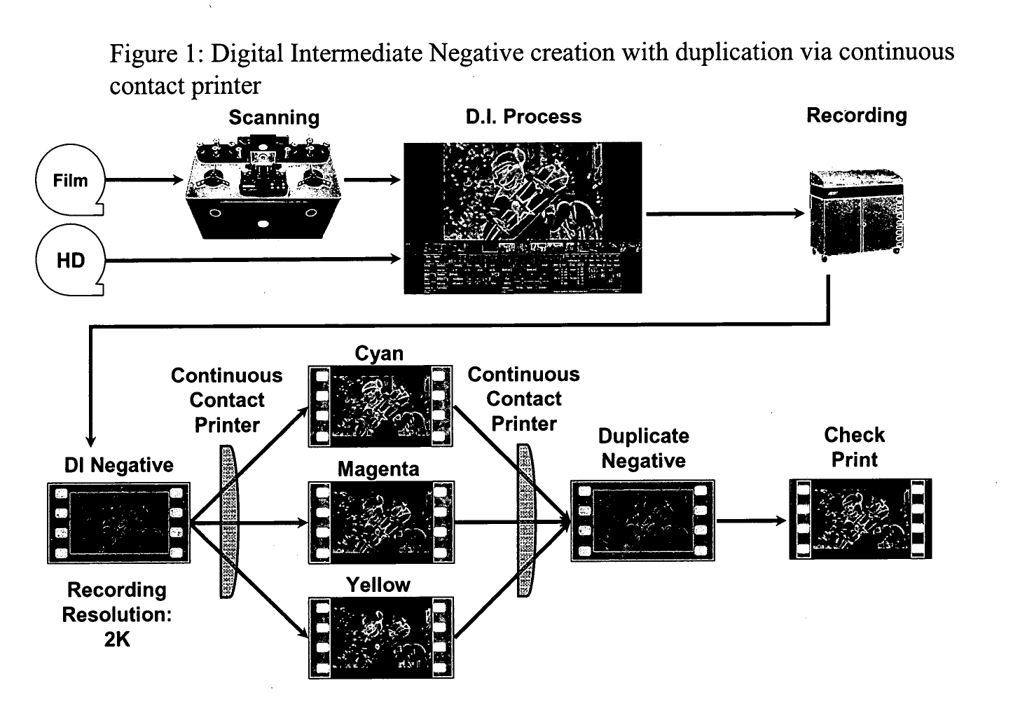

FIG. 2 illustrates the reproduction process of the instant invention.

FIG. 3 illustrates film separation transfer functions.

### DETAILED DESCRIPTION OF THE INVENTION

The present invention relates to a method for the direct conversion of visual images, such as those captured on motion picture film, and other sources, to a digital format without the generation of a Digital Intermediate. Thus, among other potential uses, which will be readily apparent to those skilled in the art, the present invention relates to a method for reproduction of a visual image such as motion picture film using digital film recording to create film elements that are stable and fade-free for very extended time periods. In other words, the produced film elements are recombined on a contact printer to create a duplicate color negative, or scanned back into a digital format so that a color negative can be digitally re-recorded. When the produced film elements are recombined on a contact printer, or scanned back into a digital format, a superior quality of reproduction is achieved when compared to prior art methods. The method of the present invention enhances the accuracy and artistic integrity of the reproduction of visual images because the final, fully reproduced digital version is not the product of a duplication step upon a contact printer from a recorded digital intermediate color negative, or what is otherwise known in the art as a Digital Intermediate (“DI”). This is because a digital process allows control of the quality of the reproduction in a manner which is not possible with prior art methods. Thus, the instant invention describes a digital process that allows control of the quality of the reproduction in a manner which is not possible with prior art methods. In other words, the instant invention describes a process that allows digital reproduction of a visual image where the quality of the reproduction can be controlled and enhanced in its digital form. In addition, the final, fully reproduced visual image has one less step in the reproduction process since a contact printer is not used to make the YCM positives, thus retaining more of the original image quality.

Each part of the transfer characteristic (e.g. contrast, color, sharpness, etc.) can be adjusted to produce a superior reproduction from the original source images. The present invention creates a digital master positive upon archival film so that a color internegative film can be produced using a pin-registered contact printer.

Other advantages of the present invention over prior art methods is that the present invention permits the validation of image data, and it produces a superior quality of the digital form of the visual images when compared to prior art methods. In the present invention the film element known as the “YCM masters” (yellow cyan magenta masters) are produced directly from the data, and not duplicated from a film negative, such as a digital visual master, as is the case for the prior art methods. The present invention also permits the validation of the data integrity of tape media data files, prior to archiving them in digital format via the preparation of a recombined negative and check print. Further advantages of the instant invention will be readily apparent to those skilled in the art.

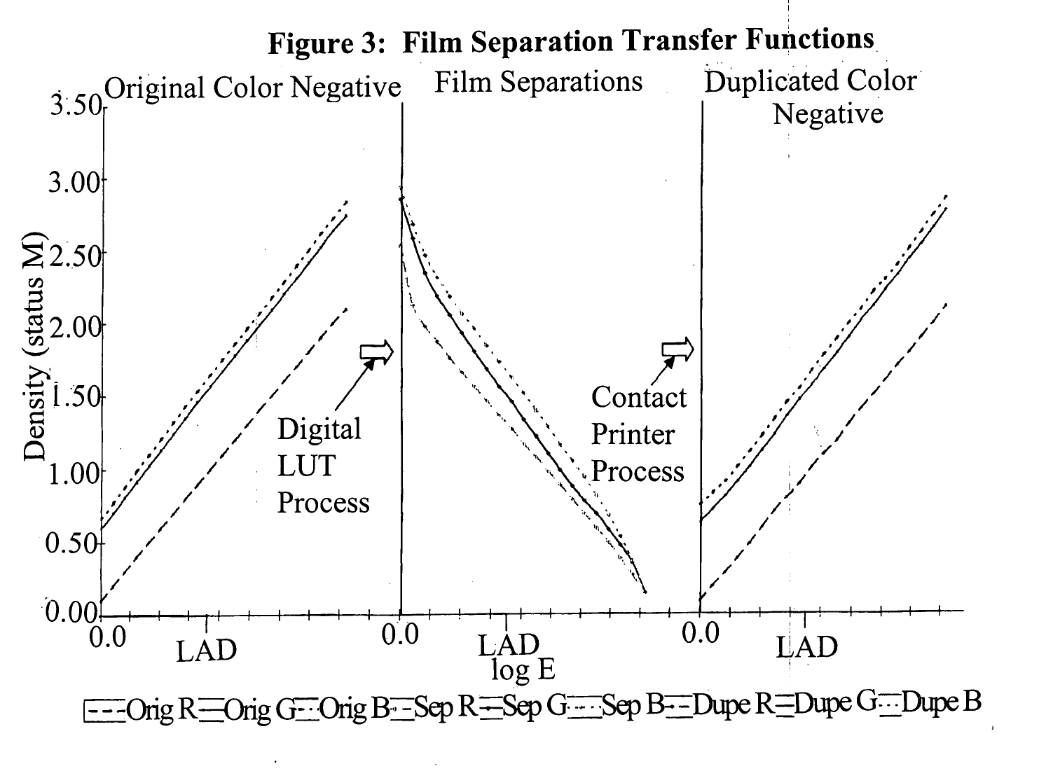

The use of digital reproduction technologies such as scanning and recording also allows enhancement of the image to achieve the best quality reproduction. While digital techniques such as digital sharpening, image resizing, transfer characteristic inversion, and color matrixing are well known in the art, the invention applies digital contrast manipulation to the entire reproduction chain so that the end result of the reproduction (the duplicated negative and check print) match the original contrast as closely as possible. An ideal reproduction would achieve a gamma slope of 1.0 for the full range of the reproduced film from D-min to Dmax. The contrast is measured in density steps between patches of grey, where any number of steps can be used as long as they each have a known stepsize from the preceding step in the series. The density steps must cover the full recordable range of densities that are possible for the film. (Dmin to Dmax). In the instant invention, the contrast of the highlight and shadow regions of the image are stretched so that the final reproduced image has a gamma slope of 1.0 allowing some roll-off and compression of the transfer characteristic at either end. See FIG. 3.

The advantage of the instant invention is that the digital YCM masters are produced as a first generation directly from the data, and not duplicated from the DI negative. The YCM film elements produced by the instant invention have been digitally pre-corrected so that the reproduction can achieve the best possible match of color between the original and the reproduced image. The visual image on the YCM master can be further enhanced by possible adjustments in contrast and sharpness to improve the final reproduced image. The instant invention results in a superior quality reproduction when compared to prior methods. Furthermore, the instant invention permits validation of the data integrity of the tape media data files, thus further ensuring the accuracy of the digitization process prior to archiving the film in digital form. Thus, the instant invention more accurately preserves the cinematographer's creative intent when compared to prior methods.

In prior practice, when the visual image has been scanned or digitized and a digital visual master recorded, a contact printer is used to duplicate the visual master. The digital visual master is also known in the art as a Digital Intermediate (DI) or Digital Master. When recorded onto color film with a digital film recorder, the film element is referred to as a “DI negative”. Meanwhile, the data files representing the visual images (i.e. the digital master) are written to a tape media. There is currently no visual check performed which confirms that these archival data files are correct. The present invention permits the validation of the data integrity of tape media data files, as the present invention includes using these files to create a visual YCM master that can then be used to create a recombined digital intermediate (DI) negative and further from this recombined DI negative, a viewable check print.

Yet another advantage of the present invention is that the digital YCM masters as produced are pin registered. The prior art method does not produce pin registered images, thus a defect called “image weaving” is introduced into the final product as a result of continuous contact printing.

Still another advantage of the present invention over the prior art is that the resolution, sharpness and contrast is not as degraded in the reproduction of the image. The resolution can be increased from the source data's 2,048 horizontal pixel resolution to 4,096 pixel resolution. Digital sharpening filters can be applied to compensate for any loss of resolution in the reproduction process. Digital manipulation of the transfer characteristic can maintain the correct original contrast throughout the reproduction chain. Digital color adjustments can be added to the data to match the original film lab's printing lights. In the case of the prior art, creating YCM masters from the digital intermediate negative introduces a reduction in resolution, to 900 lines of resolution, and a change in contrast. The prior art methods also caused a change in color. Therefore, with all these advantages, the present invention more accurately preserves the author's creative intent in the archived version of the visual work.

### EXAMPLE

This example is intended as an illustration by example of the instant invention, and not as a limitation on the method. Those skilled in the art will be aware of modifications that may be made to this process, including but not limited to, the source of the original visual image. Thus, the present invention contemplates that other visual images such as still photographs or any work that is maintained in visual form may be used as the original in this process.

In the instant invention, an original motion picture film master is digitally scanned, such that a set of digital files are created representing the color values for the amount of red, green, and blue present at every sampled pixel in the image. Any film or image source may be digitally scanned to create these files. In addition, the files may be created directly by rendering, as in computer-generated imagery (CGI) movies. In a preferred embodiment, the original film material is the original camera negative of a motion picture film, or other similar visually perceptible material. The original material may be scanned into a digital format by any method or device that converts the images on the original material into a digital format. In another preferred embodiment of the instant invention, the film or original material is scanned into a digital format by the use of a film scanning system. In yet another preferred embodiment, the scanner is calibrated and maintains a sufficient printing density space that captures the full range of color information in the original film and is thus appropriate for re-recording to film from a laser film recorder. Any color space may be used for the input device as long as the corresponding output device is calibrated in the same fashion and to the same standard as the input device so that a closed-loop calibrated color system exists. The use of the appropriate printing density spaces are well known in the art. Examples of these standards are SMPTE standards and/or Kodak Cineon standards that are known in the art. Examples of these standards are SMPTE Recommended Practice RP180-1999 “Spectral Conditions Defining Printing Density in Motion Picture Negative and Intermediate Films” and the “Kodak Digital LAD Test Image Users Guide”, Kodak Publication No. H-387, 2001.

In one form of the invention, the digital format files are processed by digital filtering methods to increase resolution to 4096 horizontal pixels and to increase visual sharpness by edge enhancement techniques known in the art. Each of the color records created by the scanning method are recorded to a strip of black and white film, where the transfer characteristic has been adjusted so that a positive image is created on the film between the maximum and minimum densities available on that particular film. These color records created by the scanning method are digitally processed to adjust color densities in each record and are recorded to the black and white strip of film as mentioned previously. This process is repeated on separate strips of black and white film for each of the red, green and blue records.

Many recorders, including laser recorders, have a characteristic ‘spot’ of light whereby heavy exposure of the light onto the film can cause a flare around the spot thus degrading the quality of the reproduced image. This is particularly a problem when recording a positive image onto a negative film as heavy exposure (creating D-max) introduces a muddy appearance to edges that are adjacent to shadow regions. To solve this problem, another preferred embodiment of the instant invention uses a black and white film where no exposure on the film yields a black (or Dmax—maximum density), and where a white (Dmin—minimum density or clear film) is created by heavy light exposure. This is the opposite of the process observed for negative film in which heavy exposure causes Dmax to increase. Any flare in the instant invention shows up as slightly expanded highlights which fits more closely to audience expectations than expanded shadow blacks which may muddy the image.

In a preferred embodiment of the invention, Kodak 2360 film is used as the black and white film, although any black and white film may be used. Kodak 2360 film is especially useful for the method of the invention because it has very fine detail characteristics that are better than most black and white films. Other preferred films include EASTMAN High Contrast Panchromatic Film 5369, 2369, or 3369, Kodak Panchromatic Separation Film 2238, EASTMAN Fine Grain Duplicating Positive Film 5366 or 7366, or EASTMAN Direct MP Film 5360 or 2360. In another preferred embodiment of the invention, the film is custom ordered with negative-type perforations, known as Bell&Howell perfs, instead of the typical KS perforations normally available for this film type. This preferred embodiment allows the operator to maintain pin registration both on the film recorder and later on the contact printer. It is expected that others skilled in the art will recognize other film types with similar properties that will be suitable for use in the invention.

Kodak 2360 film is an unexpected, yet successful, choice for this application because it has a limited dynamic range (Dmax-Dmin is less than 1.9D) according to published Kodak specifications. In the preferred embodiment, special combinations of developers are used which allow a greater density range than provided for by the film specifications. Increasing the maximum film density by 30% allows digital contrast adjustments to be made so that the film can be used as the reproduction element on a contact printer. A minimum density range of 2.6D status-M density is considered necessary for best results.

In the preferred embodiment, digital contrast adjustments are made with a custom digital calibration which compensates for the various contrast characteristics of the reproduction chain. Any suitable calibration method may be used to achieve this purpose. This preferred embodiment improves the quality of the imaging because any contact between film elements in the reproduction can decrease contrast, thus degrading the quality of the reproduction Creating a custom digital look up table for the laser recorder will compensate for the contrast change when using the film element on the contact printer to create the duplicate negative, and will also compensate for the contrast change from printing the duplicate negative onto a print film.

In another preferred embodiment in order to compensate for sharpness loss through the scanning and recording process, a slight sharpening of each frame is applied just prior to recording. Research has shown that more pleasant results are obtained when the sharpening is applied to the frame at 4 k resolution. Since the material to be recorded is delivered at 2 k resolution, it is necessary to resize up to the higher 4 k resolution.

Resizing is done using filter-based resampling techniques. The best filter function may be uncovered using a spectral response analysis as well as empirical testing. In a preferred embodiment, the best filter function for this specific task has been determined to be the Sinc function, windowed by the Cosine function, as follows: sin(PI*x)/PI*x/cos(2*PI*x) for x between −3 and 3, 0 for all other values of x.

Alternative methods that may be used include a number of other resampling filters such as bicubic (Keys), other windowed Sincs, and the Lanczos and Mitchell filters. However, the Sinc-Cos function yields the best results.

Sharpening is then performed on the resized image using the unsharp mask method, using a 7×7 gaussian blur kernel and a 75% blend value of the high frequency component (blend value is subject to change depending on type of film and quality of the material being subjected to the process).

Alternative methods include the use of a convolution kernel-based sharpening filter, or a similar unsharp mask filter with various values of the kernel radius and blend ratio. These methods can be refined by simple variation of the filters, kernel radius and blend ration followed by visual examination of the results.

In another preferred embodiment, an extended calibration phase establishes a feedback loop between the black and white developing, the laser recorder, the contact printer, the negative film type used to create the duplicate negative, the lab where the color negative is developed, plus the color print film and it's developing, this process allowing the creation of a reproduction that is closer to the original than previous methods. The goal of the feedback loop is that a gamma 1.0 film negative used as the source image will produce a gamma 1.0 reproduced negative after recompositing each of the color records. In another preferred embodiment, control strips are used in each step of the process to determine the characteristics of the process. Sensitometrically exposed control strips are used to measure and monitor lab developing of the film elements. 21 step control strips are also created on the laser film recorder to measure the actual exposure of the elements, and to evaluate the end result upon the reproduced negative.

When exposing the separation elements onto an unexposed negative, it is necessary to balance the exposure mid-point so that neither the highlights or shadows of the image are compromised. The preferred embodiment uses the Laboratory Aim Density (LAD) method to set the exposures for the mid-point of the negative's density range. A small adjustment (of less than +0.04D) is sometimes necessary to maintain proper exposure of the shadow regions onto the negative film. Those skilled in the art will readily recognize during this calibration that ‘weighting factors’ have to be given to the different steps and the skilled artisan will apply their artistic judgment about how much of a change to make to the process to get the desired reproduction result.

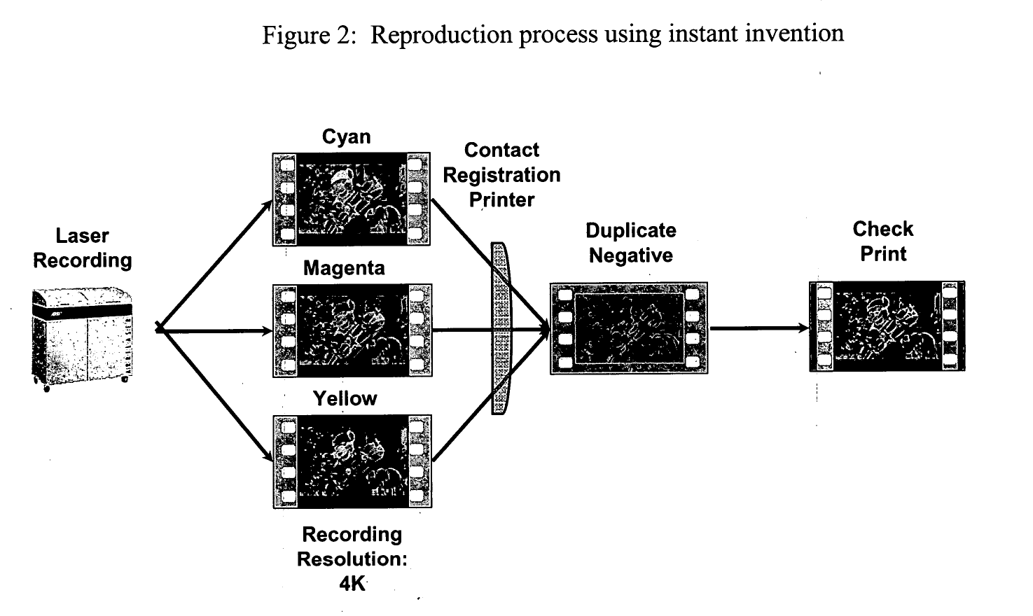

FIG. 2 illustrates an example of the process of the instant invention.

What is claimed is:

1. A method for an accurate reproduction of that visual image comprising:
converting the visually perceptible image to a digital format by scanning the original form into a digital medium, or using digital image files that have already been converted using other methods; digitally processing said converted visually perceptible images or digital image files to enhance the sharpness and resolution; performing a digital look-up transformation to modify the transfer characteristic of each color record so that a positive image is created on the film between the maximum and minimum densities available on that particular film and where the contrast characteristic has been enhanced to allow for contrast losses in the reproduction and thereby providing correct reproduction in the duplicate form of the original work; recording from the digital files separate black and white film elements each containing a red, blue or green record of the original forms color; and recombining the red, blue and green film elements into a duplicate form of the original work.

2. The method of claim 1, comprising the additional step of digitally processing the digital files to change the color characteristics of the reproduction to match the original creative intent as shown in the original answer print.

3. The method of claim 2, comprising the additional step of digitally processing the digital files to change the color characteristics to compensate for systematic calorimetric differences between the original negative and the reproduction negative.

4. The method of claim 1 where said visual image is a motion picture film.

5. The method of claim 1 wherein said scanning is performed with a film scanner and where said recording is performed with a film laser recorder.

6. The method of claim 1 wherein said film is black and white film.

7. The method of claim 6 wherein said film provides a recorded density of 2.6D or greater above base+fog density.

8. The method of claim 6 wherein said black and white film is orthochromic.

9. The method of claim 6, wherein said film is Kodak 2360 film, EASTMAN High Contrast Panchromatic Film 5369, 2369, or 3369, Kodak Panchromatic Separation Film 2238, EASTMAN Fine Grain Duplicating Positive Film 5366 or 7366, or EASTMAN Direct MP Film 5360 or 2360.

10. The method of claim 2, wherein said scanning method maintains sufficient printing density space to allow for recording onto film via a laser recorder.

11. The method of claim 6, wherein the density range of the black and white film is enhanced by a combination of developers.

12. The method of claim 6, wherein the density range of the black and white film is increased by at least 30%.

13. The method of claim 1, wherein said digital YCM masters are pin registered upon recording.

14. The method of claim 1, wherein said film has negative-type perforations, especially of the SMPTE standard Bell & Howell type.

15. The method of claim 1, wherein said method additionally includes calibration to compensate for the contrast characteristics of the reproduction chain.

16. The method of claim 1, wherein said method additionally includes digital sharpening filters to compensate for the resolution characteristics of the reproduction chain.

17. The method of claim 1 wherein said method of recombining is performed from the created color record film elements upon a contact printer.
